(19) United States
(12) Patent Application Publication
(10) Pub. No.: US 2007/0296419 A1
(43) Pub. Date: Dec. 27, 2007

(54) Insert and Pusher of Electronic Device Handling Apparatus, Socket Guide for Test Head, and Electronic Device Handling Apparatus

(75) Inventors: Mitsunori Aizawa, Tokyo (JP); Akihiko Ito, Tokyo (JP)

Correspondence Address: POSZ LAW GROUP, PLC, 12040 SOUTH LAKES DRIVE, SUITE 101, RESTON, VA, 20191, US

(73) Assignee: ADVANTEST CORPORATION, Tokyo (JP)

(21) Appl. No.: 11/791,165

(22) PCT Filed: Nov. 22, 2005
(86) PCT No.: PCT/JP05/21411

§ 371 Date: Aug. 28, 2007

(30) Foreign Application Priority Data
Nov. 22, 2004 (JP) PCT JP2004 017346

(51) Int. Cl. G01R 1/04; G01R 31/00

(52) U.S. Cl. 324/537

(57) ABSTRACT

Two electronic device holding portions 19 are formed on an insert to be attached to a test tray TST of an electronic device handling apparatus 1, and the two electronic device holding portions 19 are arranged at positions sandwiching a standard hole 20a used as a positional standard when aligning. When using an insert having a plurality of electronic device holding portions 19, the number of IC devices 2 to be held per a unit area on the test tray TST increases and the throughput improves. Also, when arranging the two electronic device holding portions 19 at positions sandwiching the standard hole 20a, both of the electronic device holding portions 19 can be close to the standard hole 20a, so that positional deviation of the IC devices 2 caused by thermal expansion or thermal contraction of the insert 16 can be suppressed and arising of contact mistakes caused by positional deviation is suppressed.

### TECHNICAL FIELD

The present invention relates to an insert and a pusher used by an electronic device handling apparatus, a socket guide used by a test head, and an electronic device handling apparatus.

### BACKGOUND ART

In a production procedure of an IC device and other electronic devices, a testing apparatus for testing finally produced electronic devices is necessary. A testing apparatus is provided with a test tray for holding an IC device, and the test tray is attached with an IC device mounting part called an insert. An insert of the related art is, as shown in FIG. 13(a), provided with an electronic device holding portion A for holding an IC device at its center part, a standard hole B for alignment formed at one end portion, and a guide hole C for aligning formed at the other end portion. The test tray is provided with, for example, 32 inserts as such, and each insert can hold an IC device.

In the testing apparatus, IC devices are held in the inserts attached to the test tray and an electronic device handling apparatus called a handler conveys the test tray to above a test head. Then, the inserts in a state of being attached to the test tray are aligned with socket guides on the test head. In this state, the respective IC devices held in the inserts are pressed against sockets on the test head by pushers. Consequently, connection terminals of the IC devices and connection terminals of the sockets are brought to be in an electrically contact state and a test is conducted by a main testing device (tester). When the test is finished, the IC devices are conveyed out from the test head by the electronic device handling apparatus, reloaded to trays in accordance with the test result and classified to respective categories, such as good ones and defective ones, etc.

### DISCLOSURE OF THE INVENTION

### Problem to be Solved by the Invention

In recent years, by increasing the number of inserts to be attached to one test tray to 32, 64 and 128, a larger number of IC devices can be tested at a time to improve the throughput. However, when the number of inserts to be attached to one tray is increased, the test tray and electronic device handling apparatus becomes large in scale. When the apparatus becomes large, it is liable that the handlability declines and the installation space becomes hard to find, so that the installation space may be limited.

Alternately, improvement of the throughput may be attained by increasing the number of IC devices to be conveyed per one unit area on the test tray by using an insert having a plurality of IC device holding portions so as to increase the number of IC devices to be tested at a time. Specifically, as shown in FIG. 13(b), there is a method of increasing the number of electronic device holding part A at the center part of the insert to two. In this case, however, a size of each insert has to be large. When testing an IC device, there is a test conducted in a state of imposing a thermal stress (heating or cooling) on the IC device. In this test, as the insert becomes larger, the size changes more largely due to the thermal expansion and thermal contraction. When a larger change arises, IC devices held in the inserts become easy to be out of alignment with sockets, so that contact mistakes due to the positional deviation easily arise.

The present invention was made in consideration of the above circumstances and has as an object thereof to provide an insert for an electronic device handling apparatus, which can improve throughput or downsize the apparatus by increasing the number of electronic devices to be tested at a time per one unit area and, moreover, arising of contact mistakes caused by positional deviation of the electronic devices can be suppressed; and an electronic device handling apparatus using the inserts.

### Means for Solving the Problem

To attain the above object, according to an invention 1, there is provided an insert of a handler for holding an electronic device to be tested and being mounted on a contact portion of a test head in that state, comprising at least two electronic device holding portions for holding electronic devices to be tested; a standard fitting portion formed between any of a plurality of the electronic device holding portions for aligning the insert; and at least one guide fitting portion for suppressing positional deviation in the direction of rotating around the standard fitting portion of the insert (an invention 1). Note that, as “the fitting portion”, a hole or a concave portion capable of fitting with a protrusion or a convex portion on the opposing side, or protrusion or a convex portion capable of fitting with a hole or a concave portion on the opposing side, etc. may be mentioned as examples.

According to the above invention (the invention 1), a plurality of electronic device holding portions can be formed closer to each other and the number of simultaneously tested electronic devices per one unit area can be increased, so that an improvement of the throughput or downsizing of the apparatus can be attained. Also, according to the above invention (the invention 1), a standard fitting portion is provided between a plurality of electronic device holding portions, so that respective electronic device holding portions can position close to the standard fitting portion. When the electronic device holding portions position close to the standard fitting portion, positional deviation of electronic device holding portion caused by thermal expansion or thermal contraction of the inserts can be suppressed efficiently. Furthermore, guide fitting portions of the insert also suppress positional deviation with respect to the standard fitting portion of the insert in the rotating direction. Accordingly, according to the above invention (the invention 1), arising of contact mistakes caused by positional deviation of the electronic devices to be tested can be suppressed.

According to the second invention, there is provided an insert of a handler for holding an electronic device to be tested and being mounted on a contact portion of a test head in that state, comprising at least two electronic device holding portions for holding electronic devices to be tested; a standard fitting portion formed between any of a plurality of the electronic device holding portions for aligning the insert in any uniaxial direction (for example, in the X-axis direction (or the Y-axis direction)); and at least two guide fitting portions for aligning the insert in an axial direction (for example, in the Y-axis direction (or the X-axis direction )) being approximately orthogonal with the direction of alignment by the standard fitting portion and suppressing positional deviation in the rotation direction of the insert (an invention 2).

According to the above invention (the invention 2), a plurality of electronic device holding portions can be formed close to each other and the number of electronic devices to be tested at a time per a unit area can be increased, so that improvement of the throughput or downsizing of the apparatus can be attained. Also, as a result that a standard fitting portion is arranged between the plurality of electronic device holding portions, positional deviation in the uniaxial direction of the electronic device holding portions caused by thermal expansion or thermal contraction of the inserts can be suppressed effectively, and positional deviation of the axial direction approximately orthogonal to the uniaxial direction can be suppressed effectively by the guide fitting portions of the inserts. Furthermore, positional deviation with respect to the standard fitting portion of the inserts can be also suppressed by the guide fitting portions of the inserts. Accordingly, according to the invention (the invention 2), arising of contact mistakes caused by positional deviation of the electronic devices to be tested can be suppressed.

In the above invention (the invention 2), preferably, the standard fitting portion aligns in the direction of connecting the two guide fitting portions by an approximately straight line (an invention 3). According to the configuration, positional deviation of the electronic device holding portions can be effectively suppressed by the standard fitting portion and the two guide fitting portions.

In the above invention (inventions 1 to 3), preferably, the standard fitting portion is formed at the center part of the insert and the guide fitting portion is formed at an end portion of the insert (an invention 4). According to the configuration, positional deviation of the electronic device holding portions can be suppressed effectively by the standard fitting portion and the guide fitting portion.

In the above invention (inventions 1 to 4), preferably, the guide fitting portion, or the standard fitting portion and the guide fitting portion are oval hole (an invention 5). As a result that the guide fitting portion is shaped as above, even if size of the insert changes due to thermal expansion or thermal contraction (particularly, size change in the longitudinal direction of the insert is larger than that in the short-side direction), a guide bush of the socket guide and a guide pin of the pusher can be inserted to the guide fitting portion so as to fit the insert, and the pusher and the socket. Also, in the width direction of the guide fitting portion, the insert is engaged by at least two guide fitting portions, so that positional deviation in the direction of rotation around the standard fitting portion of the insert can be suppressed. Fitting and removing of the insert becomes easier by forming the standard fitting portion to have an oval shape, however in this case, it is preferable that the longitudinal direction of the long hole of the standard fitting portion and the longitudinal direction of the long hole of the guide fitting portion are configured to be approximately orthogonal to each other.

In the above inventions (inventions 1 to 5), the electronic device holding portion is provided at a position corresponding to a socket arranged on a contact portion of a test head and having connection terminals for electrically contacting with terminals of an electronic device to be tested; the standard fitting portion of the insert is provided at a position of fitting with a standard fitting portion of a socket guide or a socket fixed to the contact portion for aligning the socket with the insert; and the guide fitting portion of the insert is provided at a position of fitting with a guide fitting portion of the socket guide or socket (an invention 6).

In the above inventions (inventions 1 to 6), the insert is formed a concave or convex guide portion for fitting with a convex or concave guide portion formed on a socket guide or socket capable of suppressing positional deviation in the rotation direction with respect to the socket guide or socket (an invention 7). According to the invention (the invention 7), even when the guide fitting portion of the insert is formed to have a little play with respect to the guide fitting portion of the socket guide, positional deviation in the rotation direction of the insert can be prevented, so that high dimensional accuracy is not necessary when forming the guide fitting portion.

In the above inventions (inventions 1 to 7), preferably, an electronic device to be tested held in the electronic device holding portion is pressed against connection terminals of the socket by a pressing body of a pusher; the standard fitting portion of the insert fits with a standard fitting portion of the pusher; and the guide fitting portion of the insert fits with a guide fitting portion of the pusher (an invention 8).

In the above inventions (inventions 1 to 8), the electronic device holding portion is configured so as not to interfere with an electronic device guide portion of a socket guide or socket having the electronic device guide portion for aligning an electronic device (an invention 9). By providing the electronic device guide portion to the socket guide or the socket, an electronic device can be guided by the electronic device guiding portion and brought to surely contact with terminals of the socket even if the insert thermally expands or thermally contracts, and the configuration as such can be attained according to the above invention (the invention 9).

Thirdly, according to the present invention, there is provided an insert of a handler for holding an electronic device to be tested and being mounted on a contact portion of a test head in that state, comprising a plurality of core parts having an electronic device holding portion for holding an electronic device to be tested; and a holding part for holding the plurality of core parts separately in a freely movable way (an invention 10).

According to the above invention (the invention 10), a plurality of electronic device holding portions can be formed to be close to each other and the number of electronic devices to be tested at a time per a unit area can be increased, so that an improvement of the throughput and downsizing of the apparatus can be attained. Also, according to the above invention (the invention 10), each core part is held movably by the holding part, so that positional deviation of an electronic device holding portion can be suppressed to minimum by suitably regulating a position of each core part while slightly moving it even if the insert thermally expands or thermally contracts.

In the above invention (the invention 10), preferably, each of the core parts is provided with an individual alignment fitting portion at a position of fitting with an individual alignment fitting portion provided on the contact portion side of a test head (an invention 11). According to the invention (the invention 11), each core part can be surely aligned with the contact portion, so that contact mistake caused by positional deviation of an electronic device can be suppressed.

In the above inventions (inventions 10 and 11), preferably, the holding part is formed a guide fitting portion at a position of fitting with a guide fitting portion of a socket guide or socket fixed to a contact portion of a test head (an invention 12). According to 10 the invention (invention 12), the holding part and, moreover, each core part can be surely aligned with the contact portion of the test head, so that contact mistake caused by positional deviation of an electronic device can be suppressed.

In the above inventions (inventions 10 to 12), each of the core parts is configured so as not to interfere with an electronic device guide portion of a socket guide or socket having the electronic device guide portion for aligning an electronic device (an invention 13). By providing the electronic device guiding portion to the socket guide and the socket, even if thermal expansion or thermal contraction arises in the insert, it is possible to guide an electronic device by the electronic device guide portion to surely contact with terminals of the socket, and the configuration as such can be attained according to the invention (the invention 13).

In the above inventions (inventions 1 to 13), the insert is attached to a test tray in a freely movable way (an invention 14). According to the invention (the invention 14), the insert attached to the test tray is forcibly fitted with the socket guide to keep the alignment even if the position is more or less deviated at the initial stage.

According to the present invention, fourthly, there is provided a socket guide for aligning an insert when mounting the insert comprising at least two electronic device holding portions, a standard fitting portion and a guide fitting portion to a socket of a test head, comprising at least two window holes for exposing connection terminals provided to the socket to the side of an electronic device to be tested conveyed to above the socket; a standard fitting portion for fitting with the standard fitting portion of the insert when aligning the insert; and a guide fitting portion for fitting with a guide fitting portion of the insert when aligning the insert; wherein any of a plurality of the window holes are arranged to sandwich the standard fitting portion (an invention 15).

According to the above invention (the invention 15), a socket guide capable of fitting with an insert according to the inventions (the inventions 1 to 9 and 14) explained above can be provided, consequently, the socket guide can be arranged on the test head, so that the insert and the socket guide has one to one correspondence, and alignment accuracy when aligning the insert with the socket guide can be secured easier. As a result, along with the improvement of the throughput and downsizing of the apparatus, arising of contact mistakes caused by positional deviation of the electronic device can be suppressed.

Fifthly, according to the present invention, there is provided a socket, comprising an electronic device guide portion for aligning an electronic device (an invention 16). According to the invention (the invention 16), even if thermal expansion or thermal contraction arises in the insert, an electronic device can be guided by the electronic device guiding portion to be brought to surely contact with terminals of the socket.

As a sixth point, according to the present invention, there is provided a configuration of a contact portion of a test head, attached with an insert of a handler comprising a plurality of core parts having an electronic device holding portion and a holding part for holding the plurality of core parts independently in an freely movable way, wherein the contact portion comprises an individual alignment fitting portion capable of fitting with an individual alignment fitting portion provided to each core part of the insert, and a guide fitting portion capable of fitting with a guide fitting portion provided to the holding part of the insert (an invention 17).

According to the above invention (the invention 17), a contact portion capable of fitting with the insert according to the inventions (the inventions 10 to 14) explained above can be provided, so that alignment accuracy at the time of aligning the insert with the contact portion can be secured easier. Accordingly, arising of contact mistakes caused by positional deviation of electronic device to be tested can be suppressed along with an improvement of the throughput and downsizing of the apparatus.

As the seventh point, according to the present invention, there is provided a pusher of an electronic device handling apparatus for pressing an electronic device to be tested held in an insert comprising a standard fitting portion and a guide fitting portion against a contact portion of a test head, comprising at least two pressing bodies for pressing an electronic device to be tested against the contact portion; a standard fitting portion for aligning by fitting with a standard fitting portion of the insert when pressing; and a guide fitting portion for aligning by fitting with a guide fitting portion of the insert when pressing; wherein the standard fitting portion is provided between any of a plurality of the pressing bodies (an invention 18).

According to the above invention (the invention 18), a pusher having pressing bodies by the same number as the number of electronic device holding portions of the insert according to the inventions (the inventions 1 to 14) explained above can be provided, consequently, it is possible to arrange pushers on the electronic device handling apparatus so as to attain one-to-one correspondence between the insert and the pusher.

As the eighth point, according to the present invention, there is provided an electronic device handling apparatus for conducting a test by conveying a plurality of electronic devices to be tested to a contact portion of a test head by holding them in an insert and bringing them electrically connected, comprising the insert as explained above (an invention 19).

In the above invention (the invention 19), preferably, a test chamber for maintaining a state of heating or cooling a plurality of the inserts holding electronic devices to be tested to be a predetermined temperature; a plurality of pushers for pressing the electronic devices to be tested held in the inserts against contact portions of a test head; and a drive for holding and driving the plurality of pushers so that the plurality of pushers can collectively press electronic devices to be tested held in the plurality of inserts (an invention 20).

### Advantageous Effect of the Invention

According to the insert and pusher of the electronic device handling apparatus, the socket guide for the test head, and the electronic device handling apparatus using the insert, an improvement of the throughput and downsizing of the apparatus can be attained by increasing the number of electronic devices to be tested at a time per a unit area, and arising of contact mistakes caused by positional deviation of electronic devices to be tested can be suppressed.

### BRIEF DESCRIPTION OF DRAWINGS

FIG. 1 is an overall view from the side of an IC device testing apparatus including a handler according to an embodiment of the present invention.

FIG. 2 is a perspective view of the handler according to the same embodiment.

FIG. 3 is a sectional view of a key part in a test chamber of the handler according to the same embodiment.

FIG. 4 is a disassembled perspective view showing a test tray used in the handler in the same embodiment.

FIG. 5 is a disassembled perspective view showing the configuration around a socket in the handler according to the same embodiment.

FIG. 6 is a sectional view of a part of a pusher in the handler according to the same embodiment.

FIG. 7 shows plan views of a test tray according to the same embodiment and a test tray of the related art.

FIG. 8 shows schematic plan views of configurations of inserts of other embodiments.

FIG. 9 shows views of an insert and socket guide according to another embodiment, wherein (a) shows views form the side of the insert and the socket guide and (b) shows a view from the bottom of the insert and a plan view of the socket guide.

FIG. 10 is a perspective view of an insert, pusher, socket and socket guide according to a second embodiment of the present invention.

FIG. 11 is a perspective view of the insert according to the same embodiment.

FIG. 12 shows perspective views of an insert and socket according to another embodiment.

FIG. 13 shows schematic views of sectional configurations of pushers of the related art.

### EXPLANATION OF REFERENCES

1 . . . handler (electronic device handling apparatus)
10 . . . IC device (electronic device) testing apparatus
16 . . . insert

19 . . . IC (electronic device) holding portion

20a . . . . standard hole

20b . . . . . . guide hole
30 . . . pusher

33 . . . pressing body

35a . . . standard pin

35b . . . guide pin
40 . . . socket
41 . . . socket guide

410 . . . window hole

411a . . . .. standard bush

411b . . . guide bush

### BEST MODE FOR CARRYING OUT THE INVENTION

Below, embodiments of the present invention will be explained in detail based on the drawings.

### First Embodiment

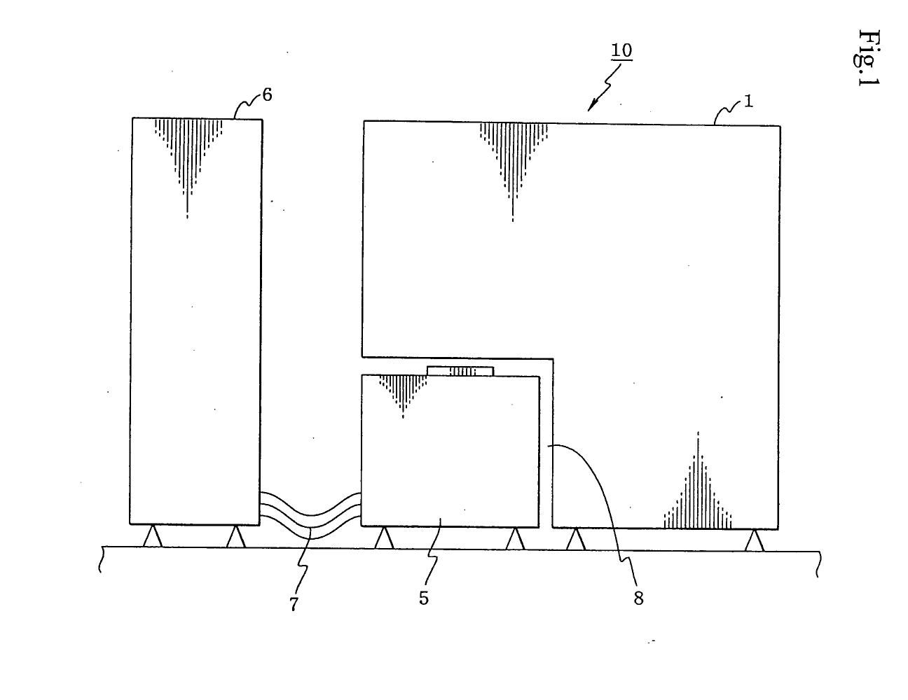

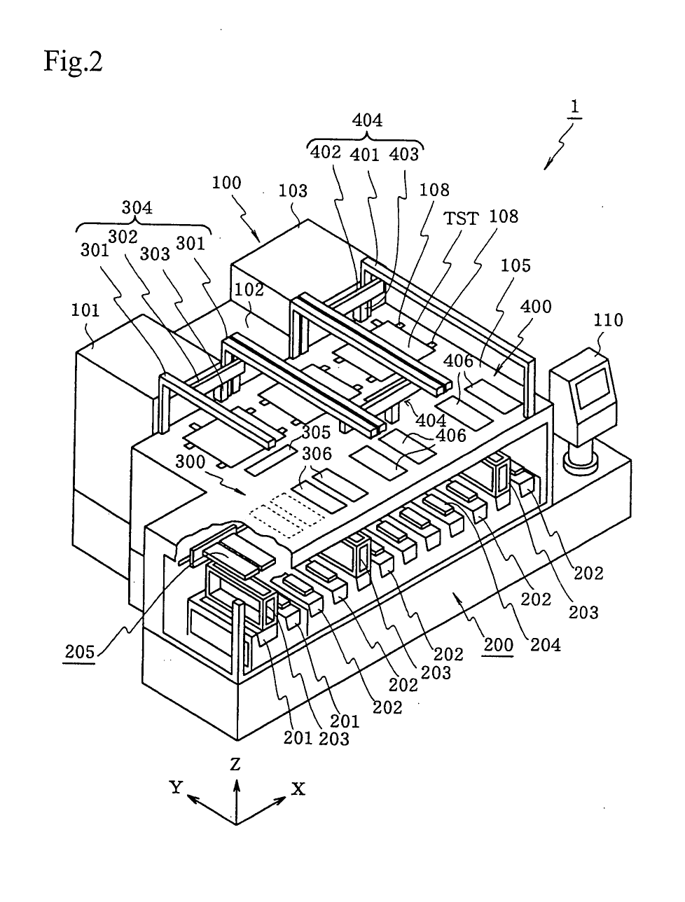

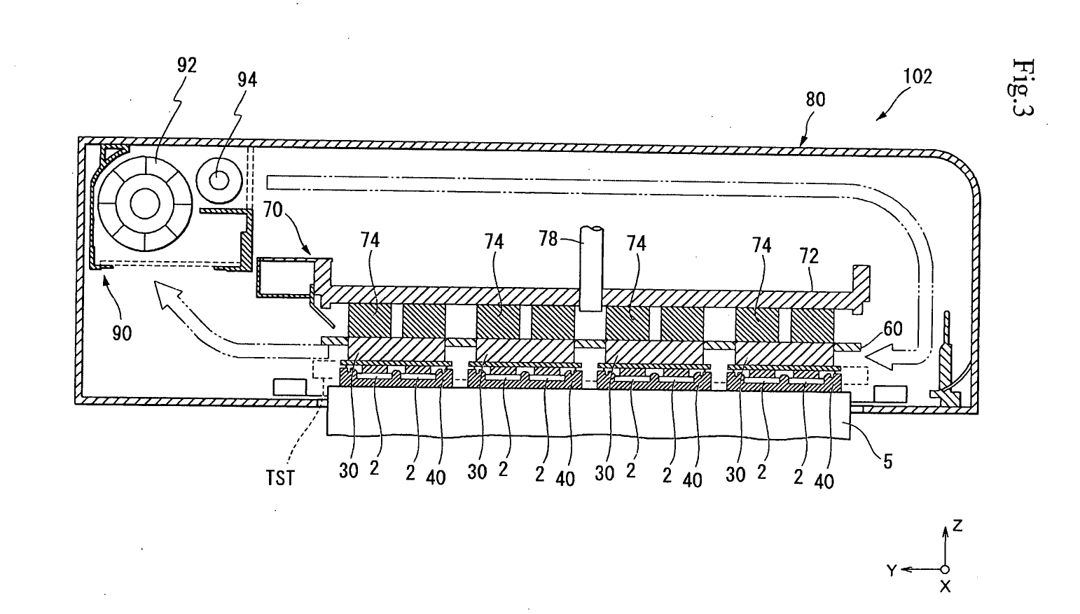

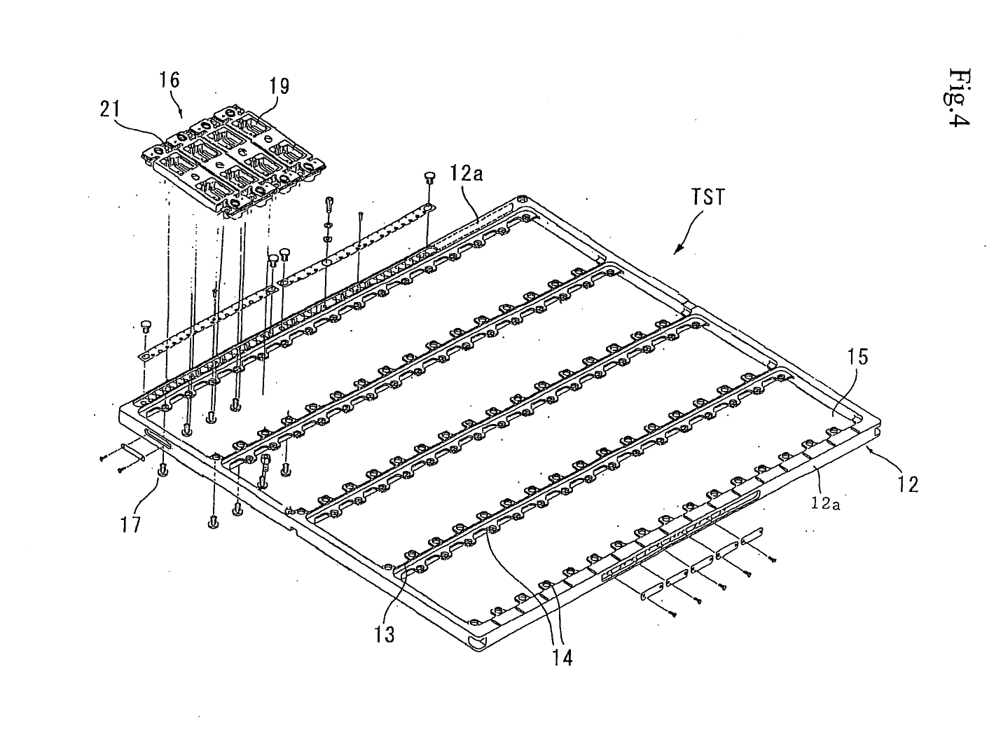

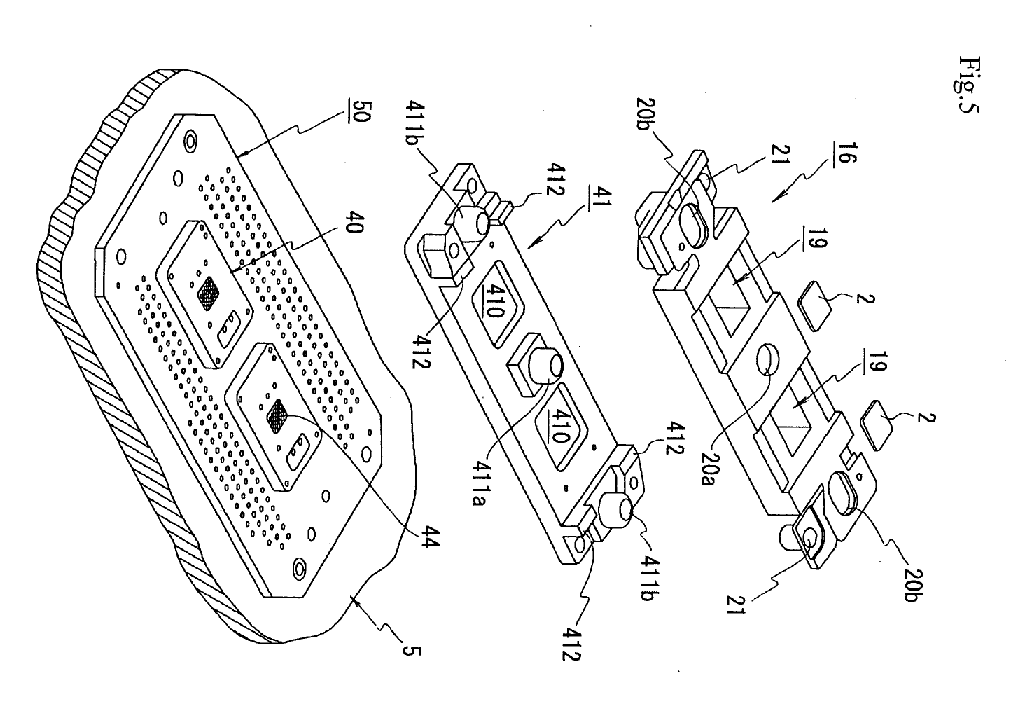

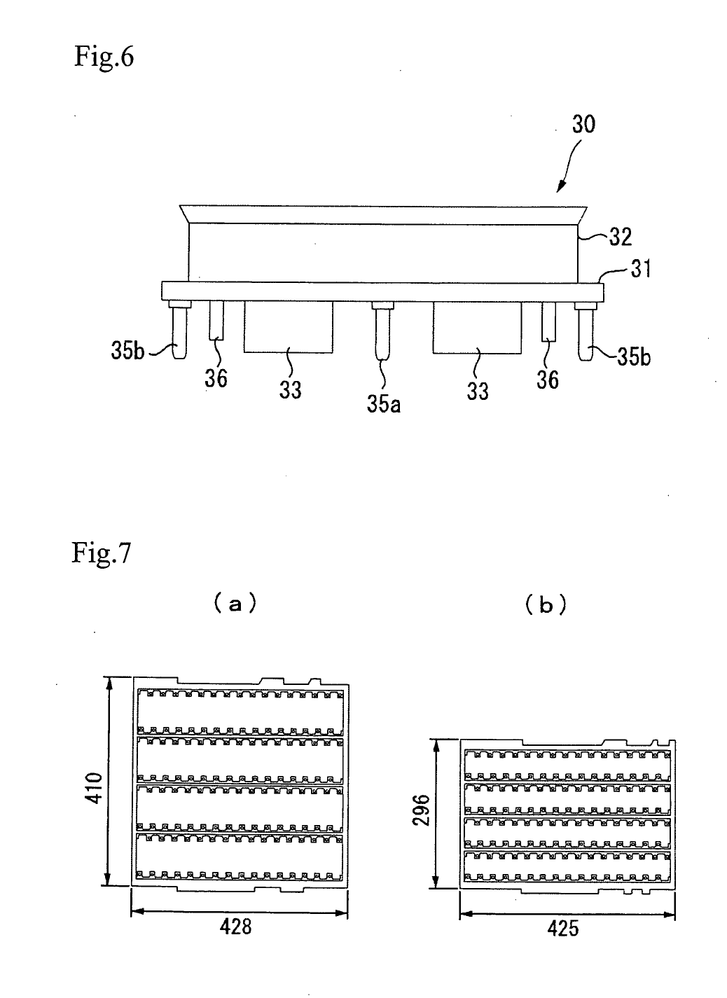

FIG. 1 is an overall view from the side of an IC device testing apparatus including an electronic device handling apparatus (hereinafter, referred to as “a handler”) according to an embodiment of the present invention; FIG. 2 is a perspective view of the handler according to the same embodiment; FIG. 3 is a sectional view of a key part in a test chamber of the handler according to the same embodiment; FIG. 4 is a disassembled perspective view showing a test tray used in the handler in the same embodiment; FIG. 5 is a disassembled perspective view showing the configuration around a socket in the handler according to the same embodiment; and FIG. 6 is a sectional view of a part of a pusher in the handler according to the same embodiment.

First, an overall configuration of an IC device testing apparatus provided with a handler according to an embodiment of the present invention will be explained.

As shown in FIG. 1, an IC device testing apparatus 10 comprises a handler 1, a test head 5 and a main testing device 6. The handler 1 performs operations of successively conveying IC devices (an example of electronic devices) to be tested to sockets provided on the test head 5, classifying tested IC devices based on the test results and loading the same on predetermined trays.

The sockets provided to the test head 5 is electrically connected to the main testing device 6 through a cable 7, and IC devices mounted detachably on the sockets are connected to the main testing device 6 through the cable 7 and tested by a testing electric signal from the main testing device 6.

In the lower portion of the handler 1, a control device for controlling mainly the handler 1 is incorporated and a space 8 is provided to a part thereof. The test head 5 is placed to be changeable in the space 8, and IC devices can be mounted on the sockets on the test head 5 through a through hole formed on the handler 1.

The handler 1 is an apparatus for testing IC devices as electronic devices to be tested in a higher temperature state (high temperature) or a lower temperature state (low temperature) than the normal temperature. The handler 1 comprises a chamber 100 composed of a constant temperature chamber 101, a test chamber 102 and an unsoak chamber 103 as shown in FIG. 2. The upper portion of the test head 5 shown in FIG. 1 is inserted to inside the test chamber 102 as shown in FIG. 3, where a test is conducted on the IC devices 2.

As shown in FIG. 2, the handler 1 of the present embodiment comprises an IC magazine 200 for holding pre-test IC devices and classifying and holding post-test IC devices, a loader section 300 for transferring IC devices to be tested sent from the IC magazine 200 to the chamber section 100, a chamber section 100 including the test head, and an unloader section 400 for taking out and classifying IC devices tested in the chamber section 100.

A large number of the IC devices are held on a not shown customer tray before being set in the handler 1 and supplied in that state to the IC magazine 200 of the handler 1 shown in FIG. 2, where the IC devices 2 are reloaded from the customer tray to a later explained test tray TST (refer to FIG. 4) used for conveying in the handler 1. Inside the handler 1, as shown in FIG. 3, the IC devices are moved in a state of being loaded on the test tray TST, given a thermal stress of a high temperature or a low temperature for testing (inspecting) whether or not they operate appropriately, and sorted in accordance with the test results.

Below, inside of the handler 1 will be explained individually in detail.

First, a part relating to the IC magazine 200 will be explained.

As shown in FIG. 2, the IC magazine 200 is provided with a pre-test IC stocker 201 for holding IC devices before tested and a post-test IC stocker 202 for holding IC devices classified in accordance with the test results.

These pre-test IC stocker 201 and post-test IC stocker 202 comprise a frame-shaped tray support frame 203 and an elevator 204 capable of entering from under the tray support frame 203 and moving upward and downward. The tray support frame 203 supports in it a plurality of stacked customer trays, and only the stacked customer trays are moved up and down by the elevator 204.

The pre-test IC stocker 201 shown in FIG. 2 holds stacked customer trays on which the IC devices to be tested are held. Also, the post-test IC stocker 202 holds stacked customer trays on which IC devices finished being tested and classified are held.

Secondary, a part relating to the loader section 300 will be explained.

The customer tray held in the pre-test IC stocker 201 is, as shown in FIG. 2, conveyed from the lower side of the apparatus substrate 105 to openings 306 on the loader section 300 by the tray transfer arm 205 provided between the IC magazine 200 and the apparatus substrate 105. Then, in the loader section 300, IC devices to be tested loaded on the customer trays are once transferred to the precisers 305 by X-Y conveyors 304, where mutual positions of the IC devices to be tested are corrected. After that, the IC devices transferred to the precisers 305 are again reloaded on the test trays TST stopped at the loader section 300 by using the X-Y conveyors 304.

The X-Y conveyor 304 for reloading the IC devices from the customer tray to the test tray TST comprises, as shown in FIG. 2, two rails 301 laid over an apparatus substrate 105, a movable arm 302 capable of moving back and forth (this direction designated as the Y-direction) between the test tray TST and the customer tray by the two rails 301, and a movable head 303 supported by the movable arm 302 and capable of moving in the X-direction along the movable arm 302.

The movable head 303 of the X-Y conveyor 304 has suction pads attached facing downward. The suction pads pick up the IC devices to be tested and reload them on the test tray TST.

Thirdly, a part relating to the chamber 100 will be explained.

The above explained test tray TST is loaded with IC devices to be tested at the loader section 300. Then, the test tray TST is sent to the chamber 100, where the respective IC devices are tested in the state of being loaded on the test tray TST.

As shown in FIG. 2, the chamber 100 comprises a constant temperature chamber 101 for giving a thermal stress of a targeted high temperature or a low temperature to the IC devices to be tested loaded on the test tray TST, a test chamber 102 wherein the IC devices in a state of being given a thermal stress in the constant temperature chamber 101 are mounted on sockets on the test head 5, and an unsoak chamber 103 for removing the given thermal stress from the IC devices tested in the test chamber 102.

In the unsoak chamber 103, the IC devices are brought back to the room temperature by ventilation when a high temperature was applied in the constant temperature chamber 101, or brought back to a temperature of a degree not causing condensation by heating by a hot air or a heater, etc. when a low temperature was applied in the constant temperature chamber 101. Then, the IC devices brought to a normal temperature are taken out to the unloader section 400.

As shown in FIG. 3, the test head 5 is arranged at a lower portion in the test chamber 102. The test tray TST carrying the IC devices 2 is transferred to be on the test head 5. On the test head 5, all IC devices 2 carried by the test tray TST are successively brought to electrically contact with the test head 5, and all IC devices 2 on the test tray TST are tested. When the test is finished, a thermal stress on the test tray TST finished with the test is removed in the unsoak chamber 103, so that the temperature of the IC devices 2 is brought to the room temperature, then, the IC devices are taken out to the unloader section 400 shown in FIG. 2.

Also, as shown in FIG. 2, at an upper portion of the constant temperature chamber 101 and the unsoak chamber 103 is formed an inlet opening for taking in the test tray TST from the apparatus substrate 105 and an outlet opening for taking out the test tray TST to the apparatus substrate 105, respectively. The apparatus substrate 105 is mounted test tray conveyors 108 for taking in and out the test tray TST to and from the openings. The conveyor 108 is composed of, for example, a rotation roller, etc. The test tray TST taken out from the unsoak chamber 103 is conveyed to the unloader section 400 by the test tray conveyor 108 provided on the apparatus substrate 105.

The test tray TST has a rectangular frame 12 as shown in FIG. 4, and the frame 12 is provided with a plurality of bars 13 in parallel at regular intervals. On both sides of the bars 13 and inside the sides 12a of the frame 12 in parallel with the bars 13 are formed a plurality of mounting tabs 14 protruding in the longitudinal direction at regular intervals. Each of insert magazines 15 is composed of two mounting tabs 14 facing to each other among the plurality of mounting tabs 14 provided between the bars 13 and between the bars and the sides 12a.

The each of the insert magazines 15 is to hold one insert 16, and the insert 16 is attached to the two mounting tabs 14 in a floating state at mounting holes 21 by using fasteners 17. In the present embodiment, the inserts 16 by the number of 4×16 are provided to one test tray TST. By holding the IC devices 2 in the inserts 16, the IC devices 2 can be loaded on the test tray TST.

As shown in FIG. 5, the insert 16 is provided at its center part with a circular standard hole 20a for being inserted a standard bush 411a of a socket guide 41, which will be explained later on. On each of two sides of the standard hole 20a, one IC holding portion 19 having an approximately rectangular shape when seen two-dimensionally from above is formed. In other word, two IC holing portions 19 are arranged at positions of sandwiching the standard hole 20a. To describe more accurately, a position of the standard hole 20a is a midpoint of the two IC holding portions 19.

Also, at the center part on both ends of the insert 16, guide holes 20b having an oval shape is formed considering thermal expansion and thermal contraction, so that the guide bushes 411b of the socket guide 41 can be inserted thereto even under a thermal stress. Each of the guide holes 20b is formed to be an oval shape, wherein the longer diameter is along the longitudinal direction of the insert 16 as shown in FIG. 5. By shaping the guide holes 20b as such, the guide bushes 411b of the socket guide 41 and guide pins 35b of the pusher 30 shown in FIG. 6 can be inserted to the guide holes 20b even if a size of the insert 16 changes due to thermal expansion or thermal contraction, so that the insert 16, and the pusher 30 and the socket 40 can be fitted together by the standard holes 20a and the guide holes 20b by using the standard holes 20a as a standard.

Next to each of the guide holes 20b is formed an attachment hole 21, which is used when attaching the insert 16 to the test tray TST.

As explained above, by forming two IC holding portions 19 on one insert 16, a space for providing an alignment means, such as standard holes 20a, can be shared by a plurality of IC holding portions 19, so that the number of IC devices 2 to be held per a unit area on the test tray TST increases. For example, the test tray shown in FIG. 7(a) is a test tray to be attached with the inserts 16 of the present embodiment each having two IC holding portions 19, and the test tray shown in FIG, 7(b) is a test tray attached with inserts 16 of the related art each having only one IC holding portion. Although the number of inserts able to be attached is 64 (4 lines by 16 rows) in both of the test trays, the number of IC devices able to be conveyed is 128 in the former test tray attached with inserts each having two IC holding portions 19, which is twice as much as that of the latter one. Furthermore, when comparing an area occupied by the respective inserts, the length of the former test tray is longer by 114 mm (which is just 1.39 times as long as that in the related art) but the width is almost equal. Therefore, according to the test tray TST of the present embodiment, IC devices 2 can be loaded at a high density. As a result that the number of IC devices 2 to be held per one unit area on the test tray TST increases as explained above, the throughput improves and the test efficiency improves.

As shown in FIG. 5, a socket board 50 is arranged on the test head 5, and a plurality of sockets 40 are fixed further thereon by forming adjacent pairs. Each socket 40 has probe pins 44 as connection terminals. The probe pins 44 are biased upward by a not shown spring. The number and pitch of the probe pins 44 correspond to those of connection terminals of an IC device 2 to be tested.

Also, a socket guide 41 is fixed on the socket board 50. The socket guide 41 has at its center part a standard bush 411a to be inserted to the standard hole 20a on the insert 16. On each of two sides of the standard bush 411a, one window hole 410 for exposing the probe pins 44 of the socket 40 to the above is formed. Namely, the socket guide 41 has window holes 410 by the number corresponding to the number of the IC holding portions 19 of one insert 16, and two window holes 410 are arranged at positions of sandwiching the standard bush 411a. To describe more accurately, a position of the standard bush 411a is a midpoint of the two window holes 410.

At the center part of each of both ends of the socket guide 41 is provided with a guide bush 411b to be inserted to the guide hole 20b of the insert 16, and two stoppers 412 for regulating the limit of downward moving of the pusher 30, which will be explained later on, are formed on both sides of each guide bush 411b. Thus, four stoppers 412 are formed in total.

Here, the standard hole 20a of the insert 16 is formed for eliminating rattling when fitted with the standard bush 411a of the socket guide 41. On the other hand, the two oval guide holes 20b on the insert 16 are formed to leave a space with the guide bush 411b in the longitudinal direction of the insert 16 and to have a hole width of a degree of not causing rattling with the guide bush 411b in its shorter direction when fitted with the guide bushes 411b on the socket guide 41.

Above the test head 5, pushers 30 for pressing IC devices 2 to be tested against the sockets 40 are provided. As shown in FIG. 6, the pusher 30 comprises a plate shaped pusher base 31 and an upper block 32 provided on the pusher base 31, and a standard pin 35a extending downward is provided at the center part of the lower surface of the pusher base 31. The standard pin 35a is inserted to the standard hole 20a on the insert 16. On each of both sides of the standard pin 35a, one pressing body 33 is formed. As explained above, the pusher 30 has pressing bodies 33 by the number corresponding to the number of IC holding portions 19 of one insert 16, and two pressing bodies 33 are arranged at positions of sandwiching the standard pin 35a. When describing more accurately, position of the standard pin 35a is a midpoint of the two pressing bodies 33.

Also, at the center part of each of both ends of the lower surface of the pusher base 31, a guide pin 35b extending downward is provided. The guide pin 35b is inserted to the guide hole 20b of the insert 16. Next to each of the guide pins 35b, two stopper pins 36 for regulating the limit of downward moving of the pusher 30 are provided, so that four stopper pins 36 are formed in total.

As shown in FIG. 3, as a result that an upper rim portion of the upper block 32 engages with an opening rim portion of the a matching plate 60, the pusher 30 is held by the matching plate 60. The matching plate 60 is supported by a drive plate 72, so that it positions above the test head 5 and a test tray TST can be inserted between the pushers 30 and the sockets 40. Pushers 30 held by matching plates 60 as such are movable in the direction of the test head 5 and the drive plate 72, that is, in the Z-axis direction.

On the lower surface of the drive plate 72, pressing portions 74 are fixed and capable of pressing an upper surface of the upper block 32 of the pusher 30. A drive axis 78 is fixed to the drive plate 72 and connected to a drive source (not shown), such as a motor, so that the drive axis 78 can be moved up and down along the Z-axis.

Note that, in the chamber 100, the test tray TST is conveyed from the orthogonal direction (X-axis) with respect to the paper surface in FIG. 3 to between the pushers 30 and the sockets 40. A conveyor roller, etc. may be used as a conveying means of the test tray TST inside the chamber 100. When conveying and moving the test tray TST, the drive plate of the Z-axis drive 70 is elevated along the Z-axis direction, and a sufficient space for the test tray TST to be inserted is formed between the pushers 30 and the sockets 40.

In the present embodiment, in the chamber 100 configured as above, as shown in FIG. 3, a temperature adjusting ventilator 90 is provided inside a tightly sealed casing 80 composing the test chamber 102. The temperature adjusting ventilator 90 comprises a fan 92 and a heat exchanger 94 and brings inside the casing 80 to be under a predetermined temperature condition (a high temperature or a low temperature) by drawing in an air inside the casing by the fan 92, letting it pass through the heat exchanger 94 and blowing to inside the casing 80 for circulation.

Fourthly, a part relating to the unloader section 400 will be explained.

The unloader section 400 shown in FIG. 2 is provided with X-Y conveyors 404 and 404 having the same configuration as that of the X-Y conveyor 304 provided to the loader section 300. Post-test IC devices are reloaded from the test tray TST conveyed out to the unloader section 400 to a customer tray by the X-Y conveyors 404 and 404.

An apparatus substrate 105 of the unloader section 400 is provided with two pairs of windows 406 and 406 arranged so that the customer trays conveyed to the unloader section 400 can be brought close from below to the upper surface of the apparatus substrate 105.

Below each of the windows 406 is provided with an elevator 204 for elevating and lowering the customer tray, in which a customer tray becoming full after being reloaded with the post-test IC devices is placed and lowered, and the full tray is given to a tray transfer arm 205.

Next, a method of testing the IC device 2 in the IC device testing apparatus 10 explained above will be explained.

The IC devices 2 in a state of being loaded on the test tray TST, that is, being dropped to be held in the IC holding portions 19 of the inserts 16 shown in FIG. 5 are conveyed to inside the test chamber 102 shown in FIG. 3 after heated to a predetermined temperature in the constant temperature chamber 101.

When the test tray TST conveyed to the test chamber 102 stops above the test head 5, the Z-axis drive 70 drives and the pressing portions 74 fixed to the drive plate 72 moves the pushers 30 downwardly. Consequently, each of the standard pins 35a of the pushers 30 is inserted to the standard hole 20a of the insert 16 and the standard bush 411a of the socket guide 41, and two guide pins 35b of the pushers 30 are inserted to guide holes 20b of the corresponding insert 16 and guide bushes 411b of the socket guide 41. At the same time, each standard bush 411a of the socket guide 41 is inserted to the standard hole 20a of the insert 16, and the guide bushes 411b of the socket guide 41 are inserted to the guide holes 20b of the insert 16. Since the socket guide 41 is aligned with the sockets 40, as a result of the operation explained above, the pushers 30, the insert 16 and the sockets 40 are aligned to one another.

The pressing bodies 33 of the pushers 30 presses package bodies of the IC devices 2 against the sockets 40 side, consequently, external terminals of the IC devices 2 are connected to probe pins 44 of the sockets 40.

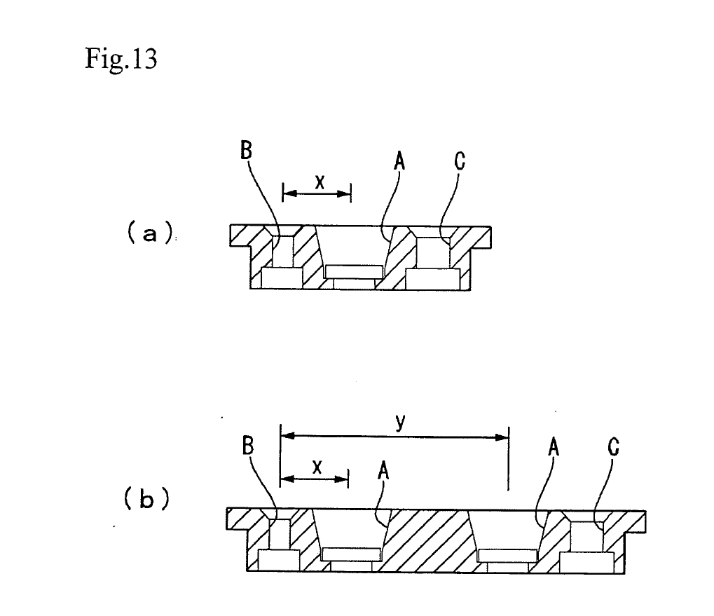

Here, the IC devices 2 held by the inserts 16 are heated (cooled) in the chamber section 100, so that sizes of the inserts 16 change due to thermal expansion (thermal contraction). However, in the case of the insert 16 of the present embodiment, wherein both of the two IC holding portions 19 are formed next to the standard hole 20a, positional deviation of the IC holding portions 19 is suppressed to minimum even if the size changes. As a result, a positional relation that connection terminals of the IC devices 2 can be connected to the probe pins 44 of the sockets 40 can be secured, so that even though the number of the IC holding portions 19 is increased, contact mistakes caused by positional deviation is prevented from arising. On the other hand, as shown in FIG. 13(b), the circumstance is different in the case of an insert, wherein two electronic device holding portions A are formed next to each other at the center part of an insert. In this insert, there are an electronic device holding portion A at a position (distance x) close to the standard hole B and an electronic device holding portion A at a position (distance y) distant from the standard hole B. In this case, large positional deviation arises due to thermal expansion or thermal contraction at the electronic device holding portion A being distant from the standard hole B, and contact mistakes caused thereby easily arise.

Also, in the longitudinal direction, the two oval guide holes 20b on the insert 16 are formed so as to leave a space with the guide bushes 411b of the socket guide 41, so that the guide holes 20b can fit with the guide bushes 411b even if thermal expansion differs between the two. On the other hand, in the short-side direction of the oval guide holes 20, the hole width is formed to be a degree of not causing rattling with the guide bushes 411b, so that the insert 16 is engaged by the two guide holes 20b and positional deviation in the direction of rotating around the standard hole 20a of the insert 16 can be eliminated. As a result, contact mistakes caused by positional deviation in the rotation direction between the external terminals of the IC devices 2 and the corresponding probe pins 44 are reduced.

Furthermore, since the insert 16 is attached in a floating state to the test tray TST, the insert 16 is slightly movable. As a result, a large number of inserts 16 on the test tray TST are forcibly fitted with standard bushes 411a of respectively corresponding socket guides 41 to be aligned and held. Accordingly, the two IC holding portions 19 arranged next to the standard bush 411a are also in a state of being suitably aligned with the respectively corresponding sockets 40. According to that, even if the overall size of the socket board 50 group caused by a change of a set temperature (for example −30° C. to +120° C.) of the test chamber 102, etc. changes, the inserts 16 and the socket guides 41 are fitted with each other, and IC devices 2 held in the two IC holding portions 19 can contact the probe pins 44 of the corresponding sockets 40 correctly.

In the above state, a testing electric signal is supplied from the main testing device 6 to the IC device 2 to be tested via the probe pins 44 of the test head 5. A response signal output from the IC device 2 is sent to the main testing device 6 through the test head 5 and used for determining whether the IC device 2 is good or defective.

When the test on the IC device 2 is finished, the Z-axis drive 70 drives to elevate the matching plate 60 (pushers 30). Then, the X-Y conveyor 404 conveys post-test IC devices 2 loaded on the test tray TST and stores them on customer trays in accordance with the test results.

### Second Embodiment

Next, an insert according to a second embodiment of the present invention will be explained.

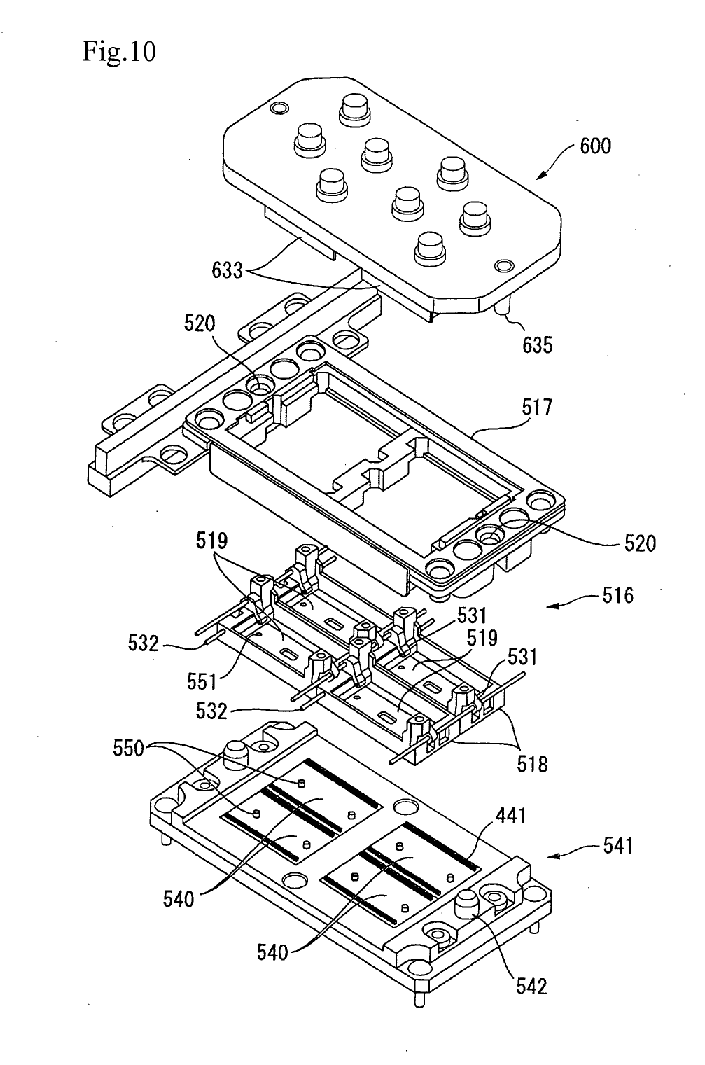

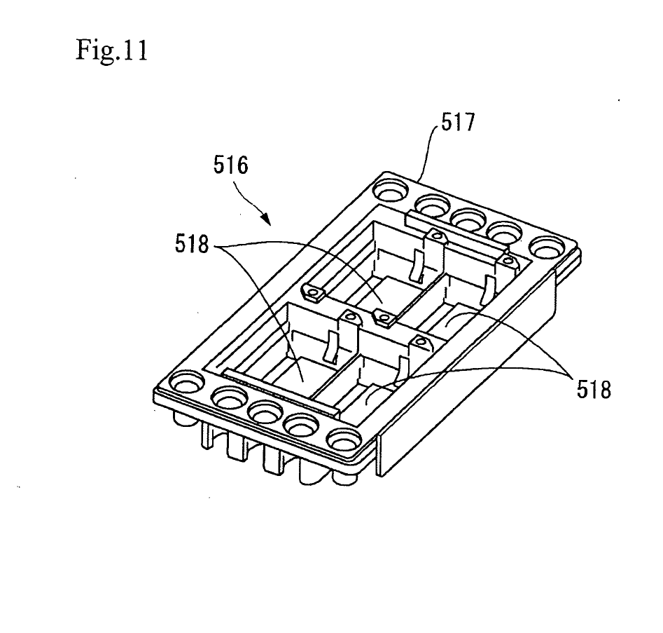

FIG. 10 is a perspective view of an insert, pusher, socket and socket guide according to the second embodiment of the present invention, and FIG. 11 is a perspective view of the insert according to the same embodiment.

As shown in FIG. 10 and FIG. 11, an insert 516 according to the present embodiment comprises 4 insert cores 518 (corresponding to core parts of the present invention) and a tray insert 517 (corresponding to a holding part of the present invention) for holding the 4 insert cores 518 in a freely movable way.

As shown in FIG. 10, each insert core 518 has one IC holding portion 519 and a latch mechanism for holding or releasing an IC device held in the IC holding portion 519 by a swaying latch member 531. On the bottom plate part of each IC holding portion 519, two individual alignment holes 551 to be fitted with two individual alignment pins 550 provided to a socket 540, which will be explained later on, are formed. Note that the insert core 518 of the present embodiment has a shape in accordance with an SOP type IC device, but it is not limited to that.

Also, two shafts 532 capable of sliding penetrate each of the insert cores 518, and the shafts 532 are attached to tray insert 517 by leaving a play for moving. Due to the configuration, each insert core 518 engages with the tray insert 517 to be able to move slightly. Note that the configuration of the freely movable mechanism of the insert core 518 is not limited to the above configuration.

At the center parts of both ends of the tray insert 517, circular guide holes 520 are formed. The tray insert 517 is attached to be freely movable to the test tray TST shown in FIG. 4 in the same way as that in the insert 16 in the above embodiment.

On the socket board of the test head, a plurality of sockets 540 are fixed so that four of them are next to one another. As shown in FIG. 10, each of the sockets 540 has connection terminals 441 corresponding to external terminals of an IC device and two individual alignment pins to be inserted to the individual alignment holes 551 formed on the insert core 518.

The socket guides 541 are fixed around the socket 540. The socket guide 541 in the present embodiment is provided with two opening window holes, through which two sockets 540 are exposed. At the center parts of both ends in the longitudinal direction of the socket guide 541, guide bushes 542 to be inserted to guide holes 520 of the tray insert 517 are provided.

A pusher base 600 of the pusher for pressing an IC device against the socket 540 has four pressing bodies 633 at positions corresponding to four sockets 540. The pressing bodies 633 may be attached to the pusher base 600 in a floating state in an individually movable way if desired. As a result, even if thermal expansion or thermal contraction arises, the IC device to be tested can be surely pressed. Also, at the center parts on both ends on the lower surface of the pusher base 600, guide pins 635 to be inserted to guide holes 520 of the tray insert 517 are provided.

When testing, the guide bushes 542 of the socket guide 541 are inserted to the guide holes 520 on the tray insert 517, the guide pins 635 provided to the pusher base 600 are inserted to the guide bushes 542 of the socket guide 541, and the respective members becomes to be in a fitted state. At this time, as a result that the guide pins 635 are inserted to the guide bushes 542 of the socket guide 541, general alignment is attained.

Here, the guide holes 520 on the tray insert 517 are formed to be a size of leaving a slight space between itself and the guide bushes 542 of the socket guide 541 considering thermal expansion due to temperature change of the members. Accordingly, when fitting as above, the tray insert 517 and the socket guide 541 becomes to be in a generally aligned state.

On the other hand, as to four insert cores and four sockets 540 facing thereto, as a result that the individual alignment holes 511 on the insert cores 518 fit with the individual alignment pins 550 of the sockets 540, the insert cores 518 are slightly moved to be aligned with the sockets 540. Therefore, external terminals of respective IC devices surely contact with connection terminals 441 of the sockets 540. Accordingly, even if temperature changes cause thermal expansion of the members, preferable contact can be realized.

The embodiments explained above are for easier understanding of the present invention and not to limit the present invention. Accordingly, respective elements disclosed in the above embodiments include all modifications in designs and equivalents belonging to the technical field of the present invention.

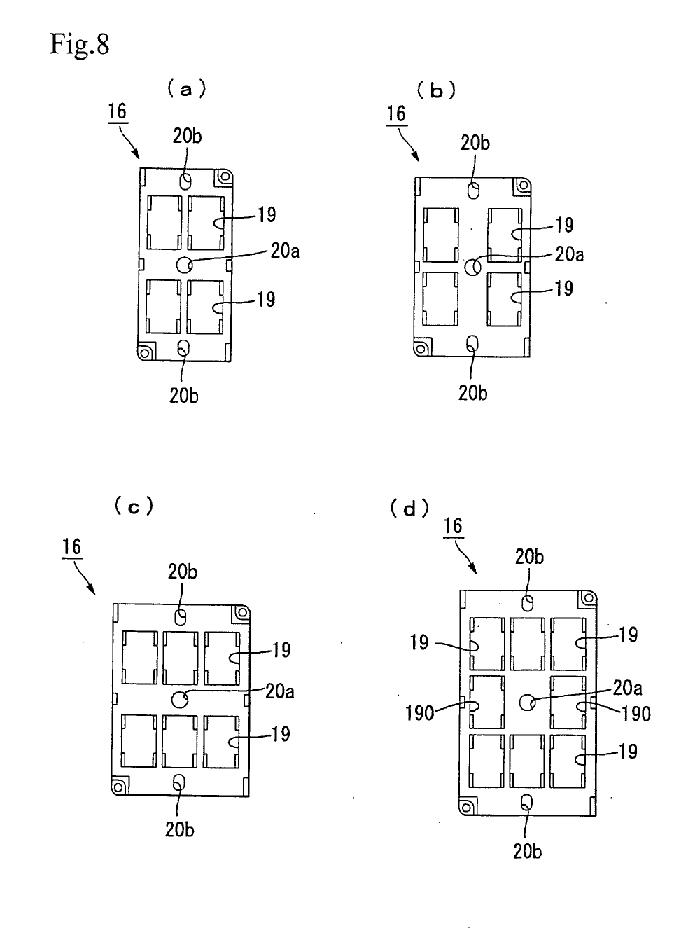

For example, in the insert 16 according to the first embodiment, the number of IC holding portions 19 on one side of the standard hole 20a is not necessarily one and, as shown in FIGS. 8(a) and (b), it may be two. In that case, IC devices can be loaded at a higher density on the test tray. Also, in the case of IC devices allowing larger positional deviations, the number of IC holding portions 19 on one side of the standard hole 20a may be three as shown in FIG. 8(c). Furthermore, as shown in FIG. 8(d), still another IC holding portion 190 may be formed next to the standard hole 20a on the insert 16. In that case, IC devices can be loaded at a furthermore higher density on the test tray.

Ideas on variation of a formation pattern of IC holding portions on the insert as such can be also applied to the case of forming window holes on the socket guide and the case of providing pressing bodies to the pusher. Namely, the number of window holes on one side of the standard bush on the socket guide may be two or three, or still another window hole may be formed at a position next to the standard bush of the socket guide. Also, the number of pressing bodies on one side of the standard pin on the pusher may be two or three, or still another pressing body may be provided at a position next to the standard pin of the pusher.

Also, when aligning the insert 16 with the socket guide 41, the number of the guide hole 20b on the insert 16 and that of the guide bush 411 on the socket guide 41 may be one, and alignment of the insert 16 with the socket guide 41 can be practically attained also by such a configuration. In that case, the guide hole 20b on one side on the insert 16 and the guide bush 411b on one side on the socket guide 41 can be omitted and furthermore downsizing can be attained. Consequently, IC devices 2 can be loaded at a still higher density on the test tray and, moreover, at a low cost.

Also, in the first embodiment, a shape of the standard hole 20a on the insert 16 is circular (refer to FIG. 5), but since guide holes 20b are engaged with the guide bushes 411b of the socket guide 41 in the short-side direction of the insert 16, it is sufficient if the standard hole 20a on the insert 16 aligns in the longitudinal direction. Therefore, if desired, the standard hole 20a may be an oval hole, wherein a width in the longitudinal direction of the insert 16 is set to be a degree of not causing rattling with the standard bush 411a and a length in the short-side direction of the insert 16 is long to leave a space between the standard bushes 411a. In that case, the insert 16 can be fitted or removed more easily.

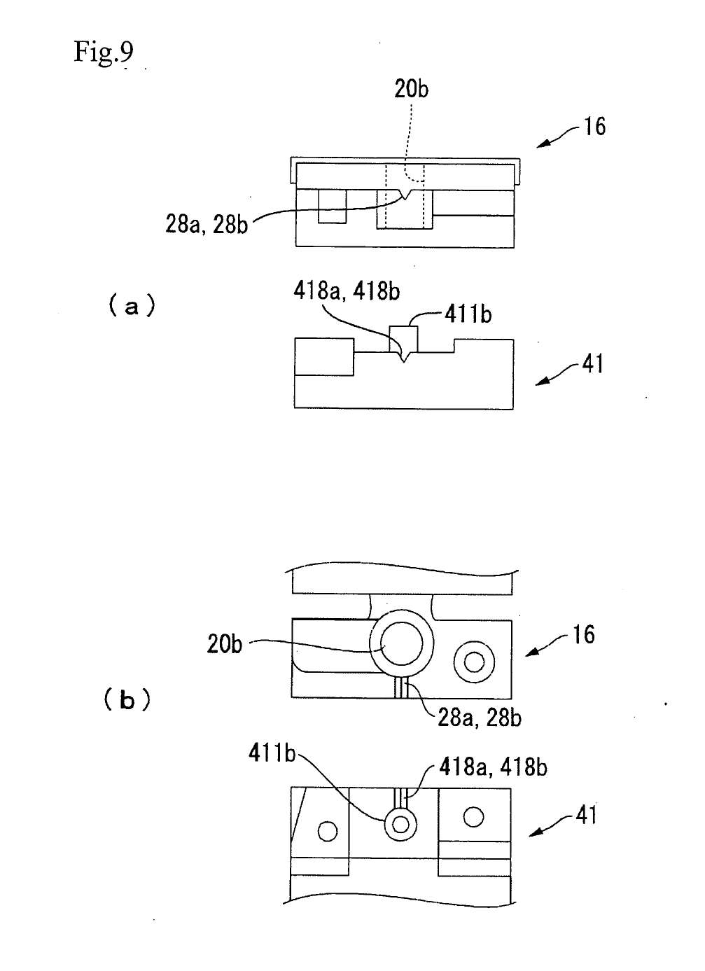

Also, the insert 16 and the socket guide 41 may be fitted to each other by the configuration as shown in FIG. 9. In an example shown in FIG. 9, the socket guide 41 is formed concave guide grooves 418a and 418b having an inverted triangle shape when seeing two-dimensionally from side at both end parts on a midline passing through the center of two guide bushes 411b when seeing two-dimensionally form above. Also, the insert 16 is formed convex guide protrusions 28a and 28b having an inverted triangle shape at positions corresponding to positions of the guide grooves 418a and 418b of the socket guide 41.

According to the above configuration, when fitting the insert 16 with the socket guide 41, the guide protrusions 28a and 28b on the insert 16 engage with the guide grooves 418a and 418b on the socket guide 41, and the fitting is attained by being guided by them. Consequently, even when thermal expansion ratios are different between the insert 16 and the socket guide 41, it hardly affect on alignment of the two and positional deviation in the direction of rotation around the standard hole 20a of the insert 16 can be eliminated. As a result, contact mistakes caused by positional deviation in the rotation direction can be reduced at the probe pins 44 corresponding to external terminals of IC devices 2.

In the case as above, a shape of the guide holes 20b on the insert 16 may be circular with a little larger diameter than that of the guide bushes 411b of the socket guide 41 instead of an oval shape.

Furthermore, in the insert 516 according to the second embodiment, four insert cores 518 are provided, but the number is not limited to that and may be any, such as two, six and eight, and the object of the present invention can be attained as far as at least two insert cores 518 are provided.

Also, in the insert core 518 of the insert 516 according to the second embodiment, individual alignment holes 551 are formed on the bottom plate part of the IC holding portion 519, but it is not limited to that and, for example, concave grooves may be formed at corners on the bottom surface side of each insert core 518. In that case, it is also applicable to IC devices of a BGA type, etc. Note that, in that case, the individual alignment pins 550 are provided to the socket guide 541.

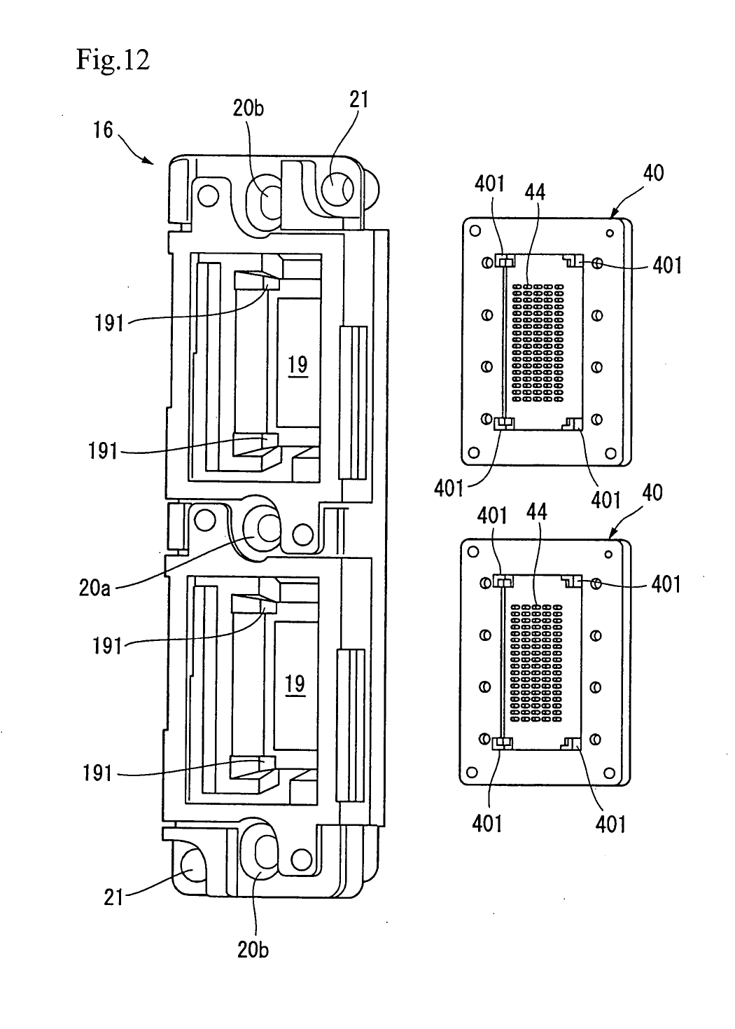

Furthermore, as shown in FIG. 12, the socket 40 may be provided with a device guide portion 401 for aligning an IC device by engaging with corners of the IC device at positions corresponding to the corners of the IC device to be mounted thereon. In the present embodiment, the device guide portion 401 has a protruding shape having a groove corresponding to a shape of the corners of the IC device. When providing such a device guide portion 401 to the socket 40, even if the insert 16 thermally expands or thermally contracts, the IC device can be guided by the device guide portion 401 and surely brought to contact with probe pins 44 of the socket 40.

When providing the device guide portions 401 as above to the socket 40, it is necessary to form escaping spaces 191 as shown in FIG. 12 in the IC holding portion 19 of the insert 16 so as not to interfere with the device guide portions 401. In the present embodiment, the escaping space 191 is formed by a hole formed on the bottom of the insert 16 and a tapered notch continuing from the hole.

Note that, in FIG. 12, the device guide portions 401 are provided on the socket 40, but it is not limited to that and they may be provided to the socket guide. Also, in the case of the insert 516 having insert cores 518, the escaping spaces are formed in the IC holding portions 519 of the insert cores 518.

### INDUSTRIAL APPLICABILITY

The insert and the pusher of an electronic device handling apparatus, the socket guide for a test head, and an electronic device handling apparatus using the insert of the present invention are useful for improving the throughput, downsizing of the apparatus and suppressing arising of contact mistakes.

1. An insert of a handler for holding an electronic device to be tested and being mounted on a contact portion of a test head in that state, comprising:
at least two electronic device holding portions for holding electronic devices to be tested;
a standard fitting portion formed between any of a plurality of said electronic device holding portions for aligning the insert; and
at least one guide fitting portion for suppressing positional deviation in the direction of rotating around said standard fitting portion of the insert.

2. An insert of a handler for holding an electronic device to be tested and being mounted on a contact portion of a test head in that state, comprising:
at least two electronic device holding portions for holding electronic devices to be tested;
a standard fitting portion formed between any of a plurality of said electronic device holding portions for aligning the insert in any uniaxial direction; and
at least two guide fitting portions for aligning the insert in an axial direction being approximately orthogonal with the direction of alignment by said standard fitting portion and suppressing positional deviation in the rotation direction of the insert.

3. The insert as set forth in claim 2, wherein said standard fitting portion aligns in the direction of connecting said two guide fitting portions by an approximately straight line.

4. The insert as set forth in claim 1, wherein said standard fitting portion is formed at the center part of the insert and said guide fitting portion is formed at an end portion of the insert.

5. The insert as set forth in claim 1, wherein said guide fitting portion, or said standard fitting portion and said guide fitting portion are oval hole.

6. The insert as set forth in claim 1, wherein:
said electronic device holding portion is provided at a position corresponding to a socket arranged on a contact portion of a test head and having connection terminals for electrically contacting with terminals of an electronic device to be tested;
said standard fitting portion of the insert is provided at a position of fitting with a standard fitting portion of a socket guide or a socket fixed to said contact portion for aligning said socket with the insert; and
said guide fitting portion of the insert is provided at a position of fitting with a guide fitting portion of said socket guide or socket.

7. The insert as set forth in claim 1, wherein said insert is formed a concave or convex guide portion for fitting with a convex or concave guide portion formed on a socket guide or socket capable of suppressing positional deviation in the rotation direction with respect to said socket guide or socket.

8. The insert as set forth in claim 1, wherein:
an electronic device to be tested held in said electronic device holding portion is pressed against connection terminals of said socket by a pressing body of a pusher;
said standard fitting portion of the insert fits with a standard fitting portion of said pusher; and
said guide fitting portion of the insert fits with a guide fitting portion of said pusher.

9. The insert as set forth in claim 1, wherein said electronic device holding portion is configured so as not to interfere with an electronic device guide portion of a socket guide or socket having the electronic device guide portion for aligning an electronic device.

10. An insert of a handler for holding an electronic device to be tested and being mounted on a contact portion of a test head in that state, comprising:
a plurality of core parts having an electronic device holding portion for holding an electronic device to be tested; and
a holding part for holding said plurality of core parts separately in a freely movable way.

11. The insert as set forth in claim 10, wherein each of said core parts is provided with an individual alignment fitting portion at a position of fitting with an individual alignment fitting portion provided on the contact portion side of a test head.

12. The insert as set forth in claim 10, wherein said holding part is formed a guide fitting portion at a position of fitting with a guide fitting portion of a socket guide or socket fixed to a contact portion of a test head.

13. The insert as set forth in claim 10, wherein each of said core parts is configured so as not to interfere with an electronic device guide portion of a socket guide or socket having the electronic device guide portion for aligning an electronic device.

14. The insert as set forth in claim 10, wherein said insert is attached to a test tray in a freely movable way.

15. A socket guide for aligning an insert when mounting the insert comprising at least two electronic device holding portions, a standard fitting portion and a guide fitting portion to a socket of a test head, comprising:
at least two window holes for exposing connection terminals provided to said socket to the side of an electronic device to be tested conveyed to above said socket;
a standard fitting portion for fitting with said standard fitting portion of the insert when aligning said insert; and
a guide fitting portion for fitting with said guide fitting portion of the insert when aligning said insert;
wherein any of a plurality of said window holes are arranged to sandwich said standard fitting portion.

16. A socket, comprising an electronic device guide portion for aligning an electronic device.

17. A configuration of a contact portion of a test head, attached with an insert of a handler comprising a plurality of core parts having an electronic device holding portion and a holding part for holding said plurality of core parts independently in an freely movable way, wherein
said contact portion comprises an individual alignment fitting portion capable of fitting with an individual alignment fitting portion provided to each core part of said insert, and a guide fitting portion capable of fitting with a guide fitting portion provided to the holding part of said insert.

18. A pusher of an electronic device handling apparatus for pressing an electronic device to be tested held in an insert comprising a standard fitting portion and a guide fitting portion against a contact portion of a test head, comprising:
at least two pressing bodies for pressing an electronic device to be tested against said contact portion;
a standard fitting portion for aligning by fitting with a standard fitting portion of said insert when pressing; and
a guide fitting portion for aligning by fitting with a guide fitting portion of said insert when pressing;
wherein said standard fitting portion is provided between any of a plurality of said pressing bodies.

19. An electronic device handling apparatus for conducting a test by conveying a plurality of electronic devices to be tested to a contact portion of a test head by holding them in an insert and bringing them electrically connected, comprising:
said insert as set forth in claim 10.

20. The electronic device handling apparatus as set forth in claim 19, comprising:
a test chamber for maintaining a state of heating or cooling a plurality of said inserts holding electronic devices to be tested to be a predetermined temperature;
a plurality of pushers for pressing the electronic devices to be tested held in said inserts against contact portions of a test head; and
a drive for holding and driving said plurality of pushers so that said plurality of pushers can collectively press electronic devices to be tested held in said plurality of inserts.
